(19) United States
(12) Patent Application Publication
(10) Pub. No.: US 2026/0090292 A1
(43) Pub. Date: Mar. 26, 2026

(54) MEMORY DEVICE

(71) Applicant: KIOXIA CORPORATION, Tokyo (JP)

(72) Inventors: Takeshi IWASAKI, Kuwana Mie (JP); Itsuko SAKAI, Kuwana Mie (JP); Tadaomi DAIBOU, Yokkaichi Mie (JP); Minoru AMANO, Yokkaichi Mie (JP); Katsuyoshi KOMATSU, Yokkaichi Mie (JP); Makoto NAGAMINE, Yokkaichi Mie (JP)

(73) Assignee: KIOXIA CORPORATION, Tokyo (JP)

(21) Appl. No.: 19/083,560

(22) Filed: Mar. 19, 2025

(30) Foreign Application Priority Data
Sep. 20, 2024 (JP) 2024-163633

(51) Int. Cl. H10N 70/00; G11C 5/06; G11C 13/00; H10B 63/00; H10N 50/10

(52) U.S. Cl. CPC H10N 70/8833; G11C 5/063; G11C 13/004; G11C 13/0069; H10B 63/80; H10N 50/10; H10N 70/826; H10N 70/841

(57) ABSTRACT

A memory device of embodiments includes a memory cell including a first conductive layer, a switching layer, a third conductive layer, a variable resistance layer, and a second conductive layer in this order. The switching layer contains a first oxide of a first element selected from Al, Si, Ge, Zr, Y, Ta, La, Ce, Ti, Hf, and Mg, a second element selected from Al, Zn, Sn, Ga, In, and Bi, and a third element selected from Te, S, Se, and Sb. The switching layer includes a first region, a second region, and a third region, and the first region is between the second region and the third region. The first region contains the first oxide, and the second region and the third region contain a second oxide of the second element or a third oxide of the third element.

### CROSS-REFERENCE TO RELATED APPLICATION

This application is based upon and claims the benefit of priority from Japanese Patent Application No. 2024-163633, filed on Sep. 20, 2024, the entire contents of which are incorporated herein by reference.

### FIELD

Embodiments described herein relate generally to a memory device.

### BACKGROUND

As a large-capacity nonvolatile memory device, there is a cross-point type two-terminal memory device. In the cross-point type two-terminal memory device, scaling-down and high integration of memory cells are easy.

Each memory cell of the cross-point type two-terminal memory device has, for example, a variable resistance element and a switching element. Since the memory cell has a switching element, the current flowing through memory cells other than the selected memory cell is suppressed.

The switching element is required to have excellent characteristics, such as low leakage current, high on-current, and high reliability.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is a schematic cross-sectional view showing a method for manufacturing a memory cell in the memory device according to the first embodiment;

FIG. 4 is a schematic cross-sectional view showing a method for manufacturing a memory cell in the memory device according to the first embodiment;

FIG. 5 is a schematic cross-sectional view showing a method for manufacturing a memory cell in the memory device according to the first embodiment;

FIG. 6 is a schematic cross-sectional view showing a method for manufacturing a memory cell in the memory device according to the first embodiment;

FIG. 7 is an explanatory diagram of the memory device according to the first embodiment;

FIG. 8 is an explanatory diagram of the current-voltage characteristic of a switching element in the first embodiment;

FIG. 9 is a schematic cross-sectional view of a memory cell in a memory device according to a first modification example of the first embodiment;

FIG. 10 is a schematic cross-sectional view of a memory cell in a memory device according to a second modification example of the first embodiment;

FIG. 11 is a schematic cross-sectional view of a memory cell in a memory device according to a third modification example of the first embodiment;

FIG. 12 is a schematic cross-sectional view of a memory cell in a memory device according to a second embodiment;

FIG. 13 is a schematic cross-sectional view of a memory cell in a memory device according to a third embodiment;

FIG. 14 is an explanatory diagram of the current-voltage characteristic of a memory element in the third embodiment;

FIG. 15 is an explanatory diagram of a first operation example of the memory operation in the memory device according to the third embodiment;

FIG. 16 is an explanatory diagram of a second operation example of the memory operation in the memory device according to the third embodiment;

FIG. 17 is an explanatory diagram of the current-voltage characteristic of a memory element according to a first modification example of the third embodiment;

FIG. 18 is an explanatory diagram of a third operation example of the memory operation in the memory device according to the first modification example of the third embodiment;

FIG. 19 is an explanatory diagram of a fourth operation example of the memory operation in the memory device according to the first modification example of the third embodiment;

FIG. 20 is an explanatory diagram of the current-voltage characteristic of a memory element according to a second modification example of the third embodiment;

FIG. 21 is an explanatory diagram of a fifth operation example of the memory operation in the memory device according to the second modification example of the third embodiment;

FIG. 22 is an explanatory diagram of a sixth operation example of the memory operation in the memory device according to the second modification example of the third embodiment;

FIG. 23 is an explanatory diagram of the current-voltage characteristic of a memory element according to a third modification example of the third embodiment;

FIG. 24 is an explanatory diagram of a seventh operation example of the memory operation in the memory device according to the third modification example of the third embodiment; and

FIG. 25 is an explanatory diagram of an eighth operation example of the memory operation in the memory device according to the third modification example of the third embodiment.

### DETAILED DESCRIPTION

A memory device of embodiments includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element different from the at least one first element and selected from a group consisting of aluminum (Al), zinc (Zn), tin (Sn), gallium (Ga), indium (In), and bismuth (Bi), and at least one third element selected from a group consisting of tellurium (Te), sulfur (S), selenium (Se), and antimony (Sb). The switching layer includes a first region, a second region, and a third region in a cross section parallel to a first direction connecting the first conductive layer and the second conductive layer, and the first region is provided between the second region and the third region in a second direction perpendicular to the first direction of the cross section. The first region contains the first oxide, and the second region and the third region contain a second oxide of the second element or a third oxide of the third element.

Hereinafter, embodiments will be described with reference to the diagrams. In addition, in the following description, the same or similar members and the like are denoted by the same reference numerals, and the description of the members and the like once described will be omitted as appropriate.

For the qualitative analysis and quantitative analysis of the chemical composition forming the memory device in this specification, for example, Rutherford backscattering spectroscopy (RBS), secondary ion mass spectroscopy (SIMS), energy dispersive X-ray spectroscopy (EDX), and electron energy loss spectroscopy (EELS) can be used. In addition, when measuring the thickness of each member forming the memory device, a distance between members, and the like, for example, a transmission electron microscope (TEM) can be used. In addition, for example, X-ray photoelectron spectroscopy (XPS), X-ray absorption fine structure (XAFS), Raman spectroscopy (Raman), scanning transmission electron microscope (STEM), or EELS can be used to identify the constituent materials of each member forming the memory device, measure the abundance ratio of the constituent materials, identify the bonding state of the constituent materials, identify the local structure (atomic distance, coordination number) of the constituent materials, measure the chemical state of the constituent materials, and compare the concentrations of the constituent materials.

### First Embodiment

A memory device according to a first embodiment includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element different from the at least one first element and selected from a group consisting of aluminum (Al), zinc (Zn), tin (Sn), gallium (Ga), indium (In), and bismuth (Bi), and at least one third element selected from a group consisting of tellurium (Te), sulfur (S), selenium (Se), and antimony (Sb). The switching layer includes a first region, a second region, and a third region in a cross section parallel to a first direction connecting the first conductive layer and the second conductive layer, and the first region is provided between the second region and the third region in a second direction perpendicular to the first direction of the cross section. The first region contains the first oxide, and the second region and the third region contain a second oxide of the second element or a third oxide of the third element.

In addition, the memory device according to the first embodiment further includes a plurality of first wirings and a plurality of second wirings crossing the plurality of first wirings. Then, the memory cell is provided in a region where one of the plurality of first wirings and one of the plurality of second wirings cross each other.

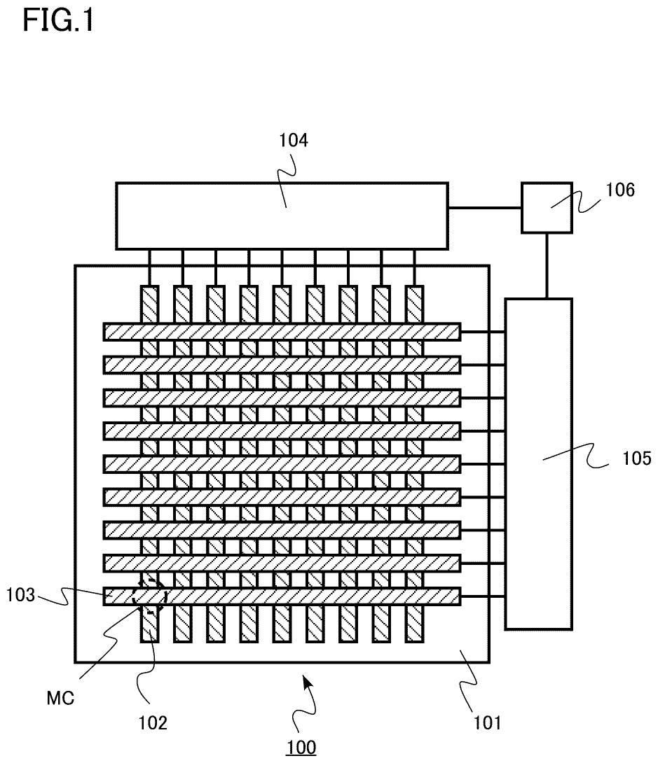

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

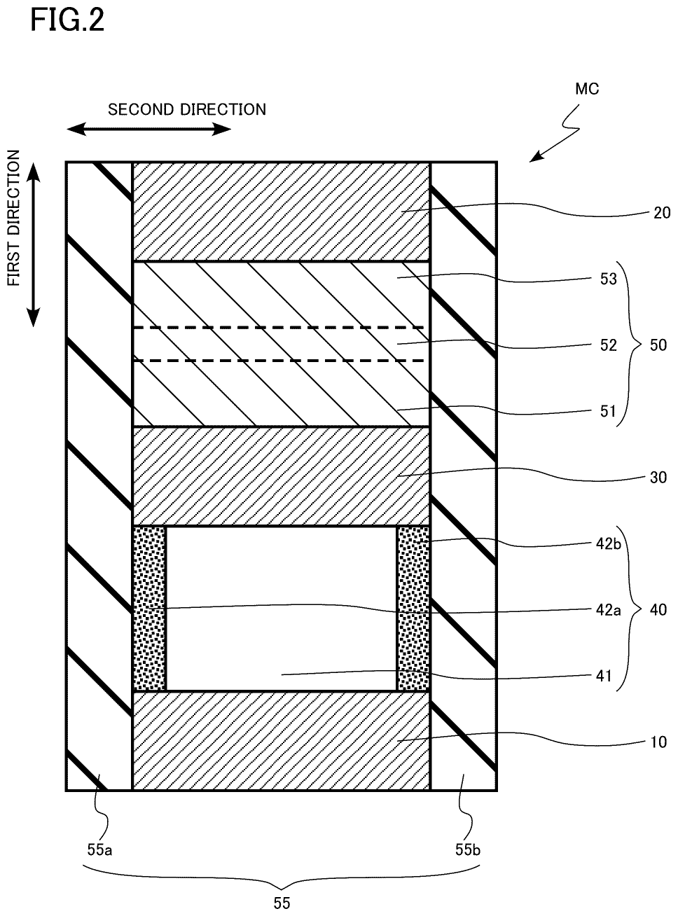

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1. FIG. 2 shows a cross section parallel to a first direction connecting a lower electrode 10 and an upper electrode 20.

As shown in FIG. 2, the memory cell MC includes a lower electrode 10, an upper electrode 20, an intermediate electrode 30, a switching layer 40, a variable resistance layer 50, and a sidewall insulating layer 55. The switching layer 40 includes an inner region 41, a first sidewall region 42a, and a second sidewall region 42b. Hereinafter, the first sidewall region 42a and the second sidewall region 42b may be referred to as a sidewall region 42 individually or collectively. The variable resistance layer 50 includes a fixed layer 51, a tunnel layer 52, and a free layer 53. The sidewall insulating layer 55 includes a first portion 55a and a second portion 55b.

The lower electrode 10 is an example of the first conductive layer. The upper electrode 20 is an example of the second conductive layer. The intermediate electrode 30 is an example of the third conductive layer. The inner region 41 is an example of the first region. The first sidewall region 42a is an example of the second region. The second sidewall region 42b is an example of the third region.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, tungsten nitride, titanium, titanium nitride, tantalum, tantalum carbide, and tantalum nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, tungsten nitride, titanium, titanium nitride, tantalum, tantalum carbide, and tantalum nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of carbon, carbon nitride, tungsten, tungsten carbide, tungsten nitride, titanium, titanium nitride, tantalum, tantalum carbide, and tantalum nitride.

The switching layer 40 is provided between the lower electrode 10 and the intermediate electrode 30. The thickness of the switching layer 40 in the first direction from the lower electrode 10 to the upper electrode 20 is, for example, equal to or more than 5 nm and equal to or less than 50 nm. It is preferable that the thickness of the switching layer 40 in the first direction from the lower electrode 10 to the upper electrode 20 is, for example, equal to or more than 5 nm and equal to or less than 20 nm. The length of the switching layer 40 in a second direction perpendicular to the first direction is, for example, equal to or more than 10 nm and equal to or less than 50 nm.

The switching layer 40 has a function of suppressing an increase in half-select leakage current flowing through a half-selected cell. The switching layer 40 has a nonlinear current-voltage characteristic that a current increases abruptly at a specific threshold voltage.

The switching layer 40 contains a first oxide of a first element, a second element, and a third element.

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg). The first oxide is, for example, an aluminum oxide, a silicon oxide, a germanium oxide, a zirconium oxide, an yttrium oxide, a tantalum oxide, a lanthanum oxide, a cerium oxide, a titanium oxide, a hafnium oxide, or a magnesium oxide.

The second element is an element different from the first element. The second element is at least one element selected from a group consisting of aluminum (Al), zinc (Zn), tin (Sn), gallium (Ga), indium (In), and bismuth (Bi). The third element is at least one element selected from a group consisting of tellurium (Te), sulfur (S), selenium (Se), and antimony (Sb).

The switching layer 40 contains, for example, a compound of the second element and the third element. The compound of the second element and the third element contains, for example, aluminum telluride, zinc telluride, tin telluride, gallium telluride, indium telluride, bismuth telluride, aluminum sulfide, zinc sulfide, tin sulfide, gallium sulfide, indium sulfide, bismuth sulfide, aluminum selenide, zinc selenide, tin selenide, gallium selenide, indium selenide, bismuth selenide, aluminum antimonide, zinc antimonide, tin antimonide, gallium antimonide, indium antimonide, or bismuth antimonide.

The sum of the atomic concentrations of the first element, the second element, the third element, and oxygen (O) in the switching layer 40 is, for example, equal to or more than 80% and equal to or less than 100%.

The ratio of the sum of the atomic concentrations of the first element and oxygen (O) to the sum of the atomic concentrations of the first element, the second element, the third element, and oxygen (O) in the switching layer 40 is, for example, equal to or more than 5% and equal to or less than 90%.

The atomic concentration of the first element contained in the switching layer 40 is, for example, equal to or more than 2% and equal to or less than 30%. The atomic concentration of the second element contained in the switching layer 40 is, for example, equal to or more than 5% and equal to or less than 50%. The atomic concentration of the third element contained in the switching layer 40 is, for example, equal to or more than 5% and equal to or less than 50%. The atomic concentration of oxygen contained in the switching layer 40 is, for example, equal to or more than 4% and equal to or less than 60%.

The switching layer 40 contains, for example, at least one fourth element selected from a group consisting of carbon (C), boron (B), and nitrogen (N). The atomic concentration of the fourth element contained in the switching layer 40 is, for example, equal to or more than 5% and equal to or less than 20%.

The switching layer 40 includes the inner region 41 and the sidewall region 42. The sidewall region 42 includes the first sidewall region 42a and the second sidewall region 42b.

In a cross section parallel to the first direction connecting the lower electrode 10 and the upper electrode 20, in the second direction perpendicular to the first direction, the inner region 41 is provided between the first sidewall region 42a and the second sidewall region 42b. The first sidewall region 42a and the second sidewall region 42b are provided, for example, between the lower electrode 10 and the intermediate electrode 30 in the first direction. The first sidewall region 42a and the second sidewall region 42b is in contact with, for example, the lower electrode 10 and the intermediate electrode 30, respectively, in the first direction.

The inner region 41 contains a first oxide, a second element, and a third element. The inner region 41 contains, for example, a compound of the second element and the third element.

The sidewall region 42 contains a second oxide of a second element or a third oxide of a third element. The sidewall region 42 contains, for example, an oxide of a second element and an oxide of a third element. The sidewall region 42 contains, for example, a first element.

The second oxide is, for example, an aluminum oxide, a zinc oxide, a tin oxide, a gallium oxide, an indium oxide, or a bismuth oxide. The third oxide is, for example, a tellurium oxide, a sulfur oxide, a selenium oxide, or an antimony oxide.

The inner region 41 contains or does not contain the second oxide or the third oxide. The concentration of the second oxide in the sidewall region 42 is, for example, higher than the concentration of the second oxide in the inner region 41. In addition, the concentration of the third oxide in the sidewall region 42 is, for example, higher than the concentration of the third oxide in the inner region 41. The concentration of the second oxide and the concentration of the third oxide are, for example, molar concentrations.

The sidewall region 42 contains or does not contain a compound of the second element and the third element. The concentration of the compound of the second element and the third element in the sidewall region 42 is, for example, lower than the concentration of the compound of the second element and the third element in the inner region 41. In addition, the concentration of the compound of the second element and the third element is, for example, a molar concentration.

The ratio of the sum of the atomic concentrations of the first element, the second element, and the third element to the sum of the atomic concentrations of the first element, the second element, the third element, and oxygen in the sidewall region 42 is, for example, lower than the ratio of the sum of the atomic concentrations of the first element, the second element, and the third element to the sum of the atomic concentrations of the first element, the second element, the third element, and oxygen in the inner region 41. The atomic concentration of oxygen in the sidewall region 42 is, for example, higher than the atomic concentration of oxygen in the inner region 41.

In addition, the atomic concentration of the second element in the sidewall region 42 is, for example, higher than the atomic concentration of the second element in the inner region 41. In addition, the atomic concentration of the third element in the sidewall region 42 is, for example, higher than the atomic concentration of the third element in the inner region 41.

The thickness of each of the first sidewall region 42a and the second sidewall region 42b in the second direction is, for example, equal to or more than 1 nm and equal to or less than 5 nm.

The variable resistance layer 50 is provided between the intermediate electrode 30 and the upper electrode 20. The variable resistance layer 50 includes the fixed layer 51, the tunnel layer 52, and the free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that its electrical resistance changes with the application of a predetermined voltage.

The fixed layer 51 is a ferromagnetic material. In the fixed layer 51, its magnetization direction does not change with respect to a predetermined write voltage, but is fixed in a specific direction.

The tunnel layer 52 is an insulator. Electrons pass through the tunnel layer 52 by the tunnel effect.

The free layer 53 is a ferromagnetic material. In the free layer 53, its magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the intermediate electrode 30 and the upper electrode 20 so that a current flow between the intermediate electrode 30 and the upper electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized. In addition, the arrangement of the fixed layer 51 and the free layer 53 may be reversed. That is, the intermediate electrode 30, the free layer 53, the tunnel layer 52, the fixed layer 51, and the upper electrode 20 may be stacked in this order.

The sidewall insulating layer 55 includes the first portion 55a and the second portion 55b. In the second direction, the lower electrode 10, the switching layer 40, and the intermediate electrode 30 are provided between the first portion 55a and the second portion 55b. For example, the first sidewall region 42a is in contact with the first portion 55a. In addition, the second sidewall region 42b is in contact with the second portion 55b.

The chemical composition of the sidewall insulating layer 55 is different from the chemical composition of the sidewall region 42. The sidewall insulating layer 55 is, for example, a silicon oxide.

Next, a method for manufacturing a memory cell in the memory device according to the first embodiment will be described.

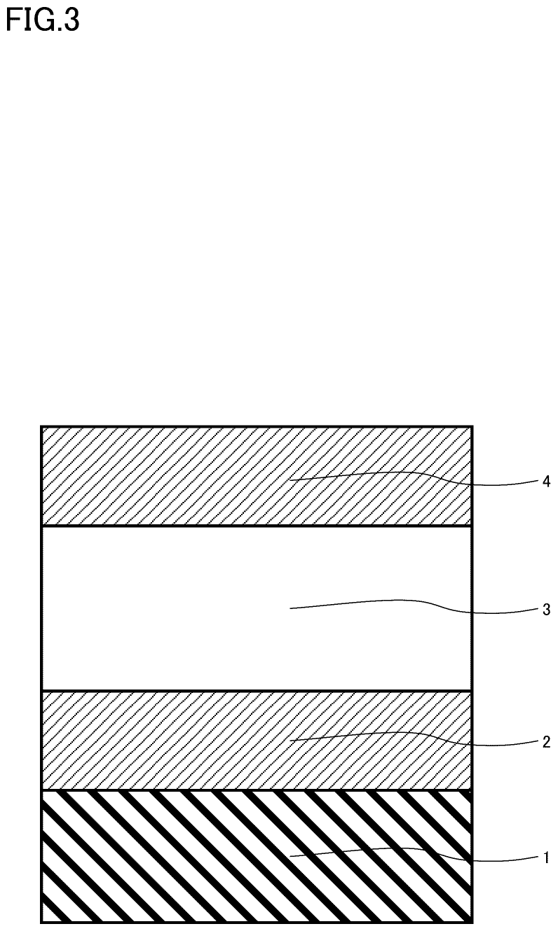

FIGS. 3 to 6 are schematic cross-sectional views showing a method for manufacturing a memory cell in the memory device according to the first embodiment. FIGS. 3 to 6 are cross-sections corresponding to FIG. 2.

Hereinafter, a case where the first element is zirconium (Zr), the second element is zinc (Zn), and the third element is tellurium (Te) will be described as an example.

First, a first carbon film 2, a zirconium oxide film 3 containing zinc (Zn) and tellurium (Te), and a second carbon film 4 are formed on a substrate 1 (FIG. 3).

The substrate 1 is, for example, a conductive layer. The first carbon film 2, the zirconium oxide film 3 containing zinc (Zn) and tellurium (Te), and the second carbon film 4 are formed by using, for example, a sputtering method. The first carbon film 2, the zirconium oxide film 3 containing zinc (Zn) and tellurium (Te), and the second carbon film 4 finally become the lower electrode 10, the switching layer 40, and the intermediate electrode 30, respectively.

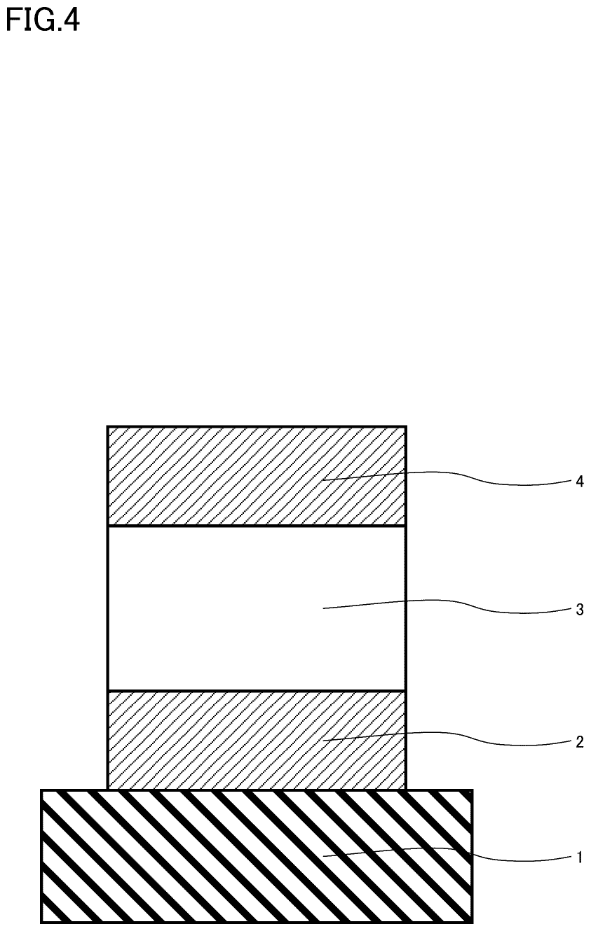

Then, a resist pattern is formed on the second carbon film 4 by using a lithography method. Then, reactive ion etching (RIE) is performed using the resist as a mask to process the second carbon film 4, the zirconium oxide film 3 containing zinc (Zn) and tellurium (Te), and the first carbon film 2 (FIG. 4).

The etching gas used during the RIE contains, for example, chlorine (Cl). After the RIE, for example, in order to prevent chlorine from remaining in the zirconium oxide film 3 containing zinc (Zn) and tellurium (Te), a treatment is performed in an atmosphere containing hydrogen gas.

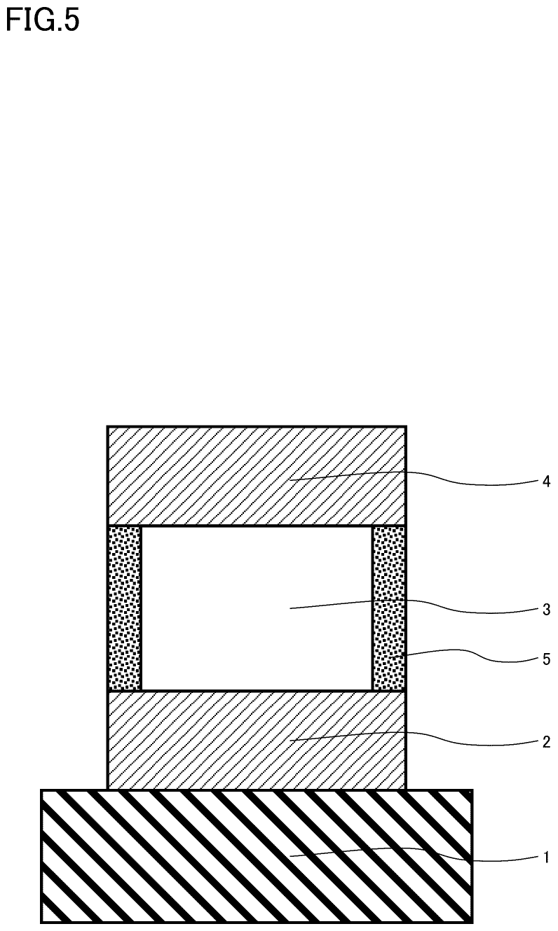

Then, an oxidation treatment is performed to oxidize the side surfaces of the zirconium oxide film 3 containing zinc (Zn) and tellurium (Te) (FIG. 5). The oxidation treatment is performed using oxygen plasma. The oxidation treatment is performed in the same chamber as for the RIE. The RIE, the treatment in an atmosphere containing hydrogen gas, and the oxygen treatment are performed successively in the same chamber. The RIE, the treatment in an atmosphere containing hydrogen gas, and the oxygen treatment are performed without exposing the substrate 1 to the atmosphere outside the chamber.

By the oxidation treatment, an oxidized region 5 is formed on the side surfaces of the zirconium oxide film 3 containing zinc (Zn) and tellurium (Te). In the oxidized region 5, for example, a zinc oxide and a tellurium oxide are formed. The oxidized region 5 finally becomes the sidewall region 42.

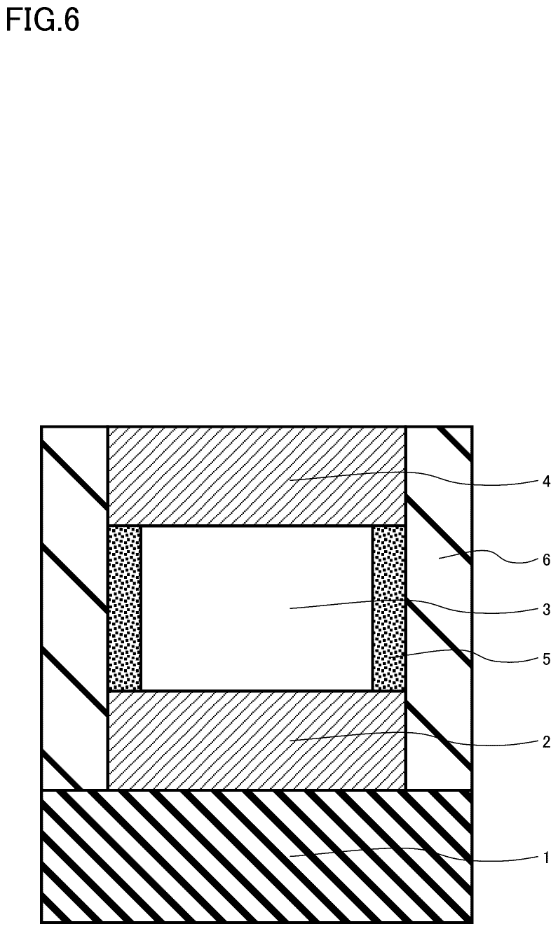

Then, a silicon oxide film 6 is formed on the side surfaces of the first carbon film 2, the zirconium oxide film 3 containing zinc (Zn) and tellurium (Te), and the second carbon film 4 (FIG. 6). The silicon oxide film 6 is formed by using, for example, a chemical vapor deposition method. The silicon oxide film 6 finally becomes the sidewall insulating layer 55.

Thereafter, a variable resistance layer 50 and the upper electrode 20 are formed by using a known manufacturing method. Through the manufacturing method described above, the memory cell in the memory device according to the first embodiment is formed.

Next, the function and effect of the memory device according to the first embodiment will be described.

In the memory device according to the first embodiment, as described above, the resistance of the variable resistance layer 50 is changed by changing the magnetization direction of the free layer 53. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”. Writing to one memory cell MC is performed by applying a voltage between the bit line 103 and the word line 102 connected to the memory cell MC so that a current flows between the bit line 103 and the word line 102 connected to the memory cell MC.

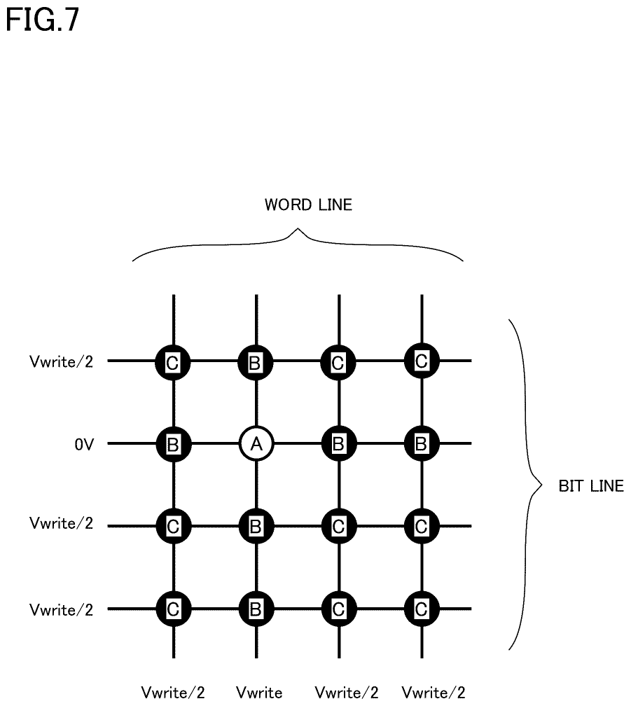

FIG. 7 is an explanatory diagram of the memory device according to the first embodiment. FIG. 7 shows a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half (Vwrite/2) the write voltage is applied to the word lines and bit lines that are not connected to the memory cell A will be described as an example.

A voltage applied to memory cells C (unselected cells) connected to the word lines and bit lines that are not connected to the memory cell A is 0 V. That is, no voltage is applied.

On the other hand, half (Vwrite/2) the write voltage Vwrite is applied to memory cells B (half-selected cells) connected to the word lines or bit lines connected to the memory cell A. Therefore, a half-select leakage current flows through the memory cell B (half-selected cell).

In addition, as an application method other than those described above, a method may be used in which half the write voltage (Vwrite/2) is applied to the word line connected to the memory cell A, a negative voltage (−Vwrite/2) of half the write voltage is applied to the bit line, and 0 V is applied to the word line and the bit line that are not connected to the memory cell A.

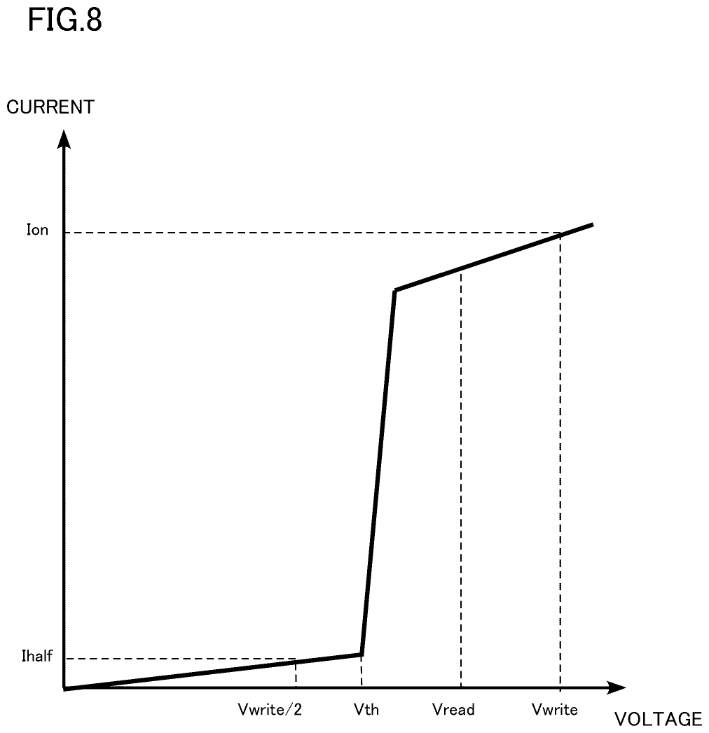

FIG. 8 is an explanatory diagram of the current-voltage characteristic of a switching element in the first embodiment. The horizontal axis indicates a voltage applied to the switching element, and the vertical axis indicates a current flowing through the switching element.

The switching element has a nonlinear current-voltage characteristic that the current increases abruptly at a threshold voltage Vth. The threshold voltage Vth is, for example, equal to or more than 0.5 V and equal to or less than 3 V.

The write voltage Vwrite is set such that the write voltage Vwrite is higher than the threshold voltage Vth and half (Vwrite/2) the write voltage Vwrite is lower than the threshold voltage Vth. The current flowing through the switching element when the write voltage Vwrite is applied is an on-current (Ion in FIG. 8). The current flowing through the switching element when half (Vwrite/2) the write voltage Vwrite is applied is a half-select leakage current (Ihalf in FIG. 8).

In addition, a read voltage Vread of the memory cell MC is set to a voltage higher than the threshold voltage Vth and lower than the write voltage Vwrite, as shown in FIG. 8, for example. Therefore, the half-select leakage current flowing through the half-selected cell can also be suppressed when reading the memory cell MC.

If the half-select leakage current is large, for example, the power consumption of the chip increases. In addition, for example, a voltage drop in the wiring increases and accordingly, a sufficiently high voltage is not applied to the selected cell. As a result, an operation for writing to the memory cell MC becomes unstable. In addition, if the on-current is small, for example, the current flowing through the selected cell is insufficient, resulting in insufficient writing to the memory cell MC. Therefore, as the current-voltage characteristic of the switching element, it is required to have both a low half-select leakage current and a high on-current.

In addition, high reliability is required for the current-voltage characteristic of the switching element. That is, it is required to realize high reliability by suppressing fluctuations in characteristics such as fluctuations in on-current or fluctuations in half-select leakage current when repeating data writing to the memory cell MC.

For example, as a switching element according to a comparative example, a switching element in which a switching layer does not include the sidewall region 42 is considered. The switching layer that does not include the sidewall region 42 can be formed, for example, by processing the switching layer using RIE and then performing no oxidation treatment on the side surface. The switching element according to the comparative example has a problem such as a high half-select leakage current or large fluctuations in characteristics when repeating data writing to the memory cell MC.

One of the causes of the above problem occurring in the switching element according to the comparative example is believed to be that the second element or the third element is present on the sidewall of the switching layer locally as a single material, not as a compound. Since the second element or the third element is present on the sidewall of the switching layer as a single material, a current leakage path is formed to increase the half-select leakage current. In addition, it is believed that, since the second element or the third element is present on the sidewall of the switching layer as a single material, agglomeration of the second element or the third element when repeating data writing to the memory cell MC is accelerated to increase fluctuations in characteristics.

If the side surface of the switching layer is not oxidized after processing the switching layer by RIE, damage caused by etching remains on the side surface of the switching layer. For example, when the switching layer is exposed to the atmosphere, it is believed that the second element or the third element is present on the sidewall of the switching layer as a single material due to damage caused by etching.

The switching layer 40 in the first embodiment includes the sidewall region 42 on the sidewall. The sidewall region 42 contains a second oxide in which a second element is oxidized or a third oxide in which a third element is oxidized. The sidewall region 42 may contain a first oxide of the first element. In the sidewall region 42, the second oxide or the third oxide is formed by oxidizing the second element or the third element through the oxidation treatment. Therefore, the presence of the second element or the third element as a single material on the sidewall of the switching layer 40 is suppressed. As a result, according to the switching element in the first embodiment, it is possible to realize a low half-select leakage current and suppression of fluctuations in characteristics.

From the viewpoint of improving the characteristics of the switching element, it is preferable that the sidewall region 42 contains both the second oxide and the third oxide.

It is preferable that the concentration of the second oxide in the sidewall region 42 is higher than the concentration of the second oxide in the inner region 41. In addition, it is preferable that the concentration of the third oxide in the sidewall region 42 is higher than the concentration of the third oxide in the inner region 41. The presence of the second element or the third element as a single material on the sidewall of the switching layer 40 is further suppressed to further improve the characteristics of the switching element.

It is preferable that the concentration of the compound of the second element and the third element in the sidewall region 42 is lower than the concentration of the compound of the second element and the third element in the inner region 41. Since the compound becomes an oxide, the leakage current at the sidewall of the switching layer 40 is further suppressed to further improve the characteristics of the switching element.

According to the first embodiment, even if the atomic concentration of the second element in the sidewall region 42 is higher than the atomic concentration of the second element in the inner region 41, the second element is fixed as a second oxide, thereby improving the characteristics of the switching element. Similarly, according to the first embodiment, even if the atomic concentration of the third element in the sidewall region 42 is higher than the atomic concentration of the third element in the inner region 41, the third element is fixed as a third oxide, thereby improving the characteristics of the switching element. For example, during the oxidation treatment, the distribution of the first element, the second element, or the third element in the switching layer 40 may change, and accordingly, the atomic concentration of the second element in the sidewall region 42 may become higher than the atomic concentration of the second element in the inner region 41 or the atomic concentration of the third element in the sidewall region 42 may become higher than the atomic concentration of the third element in the inner region 41.

From the viewpoint of suppressing the leakage current at the sidewall of the switching layer 40 to improve the characteristics of the switching element, it is preferable that the sidewall region 42 is in contact with the lower electrode 10 and the intermediate electrode 30 in the first direction.

It is preferable that the switching layer 40 contains at least one fourth element selected from a group consisting of carbon (C), boron (B), and nitrogen (N). Since the switching layer 40 contains the fourth element, crystallization of the switching layer 40 is suppressed to reduce the half-select leakage current, for example.

### First Modification Example

A memory device according to a first modification example of the first embodiment is different from the memory device according to the first embodiment in that a first conductive layer includes a first portion and a second portion and the first portion contains at least one element selected from hafnium (Hf), aluminum (Al), magnesium (Mg), zirconium (Zr), and titanium (Ti).

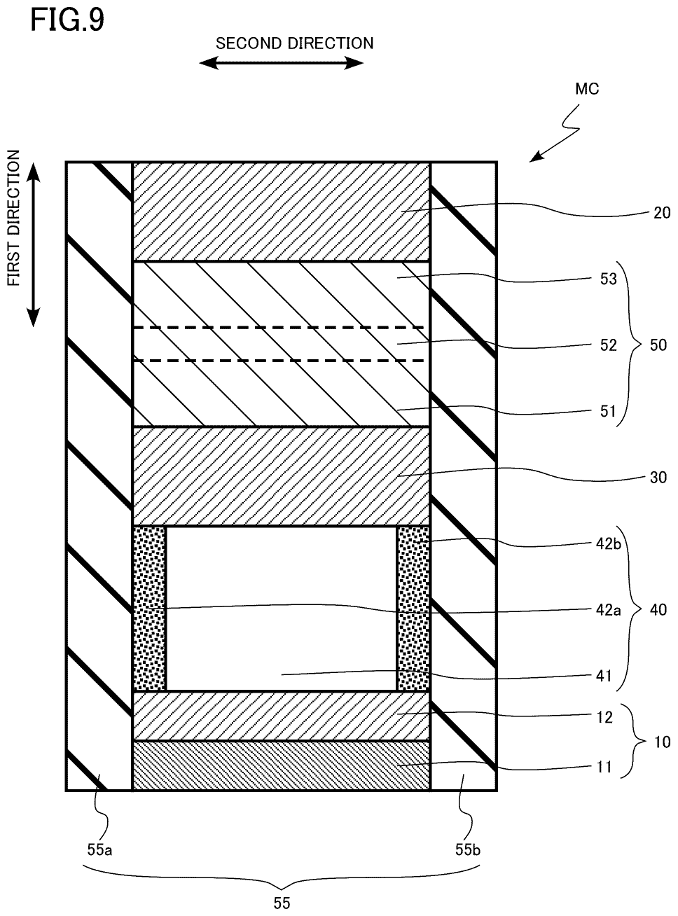

FIG. 9 is a schematic cross-sectional view of a memory cell in the memory device according to the first modification example of the first embodiment. FIG. 9 is a diagram corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, aluminum magnesium boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

In the memory device according to the first modification example of the first embodiment, the first portion 11 of the lower electrode 10 contains at least one element selected from hafnium (Hf), aluminum (Al), magnesium (Mg), zirconium (Zr), and titanium (Ti), thereby suppressing the degradation of the characteristics of the variable resistance element. In addition, since the first portion 11 is not in contact with the switching layer 40, desorption of oxygen (O) from the switching layer 40 is suppressed and accordingly, degradation of the characteristics of the switching element is suppressed.

As described above, according to the first modification example of the first embodiment, as in the first embodiment, it is possible to realize a switching element having excellent characteristics such as a low half-select leakage current and high reliability.

### Second Modification Example

A memory device according to a second modification example of the first embodiment is different from the memory device according to the first embodiment in that a first conductive layer includes a first portion and a second portion, the first portion contains at least one element selected from hafnium (Hf), aluminum (Al), magnesium (Mg), zirconium (Zr), and titanium (Ti), a second conductive layer contains one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

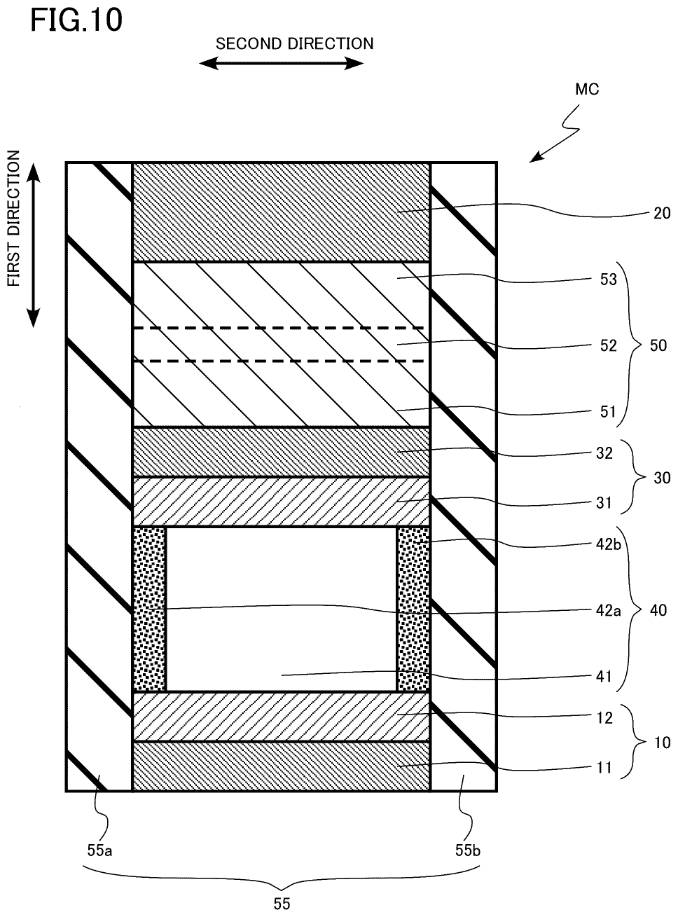

FIG. 10 is a schematic cross-sectional view of a memory cell in the memory device according to the second modification example of the first embodiment. FIG. 10 is a view corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the second modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the second modification example of the first embodiment, as in the first embodiment, it is possible to realize a switching element having excellent characteristics such as a low half-select leakage current and high reliability.

### Third Modification Example

A memory device according to a third modification example of the first embodiment is different from the memory device according to the first embodiment in that a first conductive layer includes a first portion, a second portion, and a fifth portion, the first portion contains at least one element selected from hafnium (Hf), aluminum (Al), magnesium (Mg), zirconium (Zr), and titanium (Ti), a second conductive layer contains at least one element selected from hafnium (Hf), aluminum (Al), magnesium (Mg), zirconium (Zr), and titanium (Ti), a third conductive layer includes a third portion and a fourth portion, and the fourth portion contains at least one element selected from hafnium (Hf), aluminum (Al), magnesium (Mg), zirconium (Zr), and titanium (Ti).

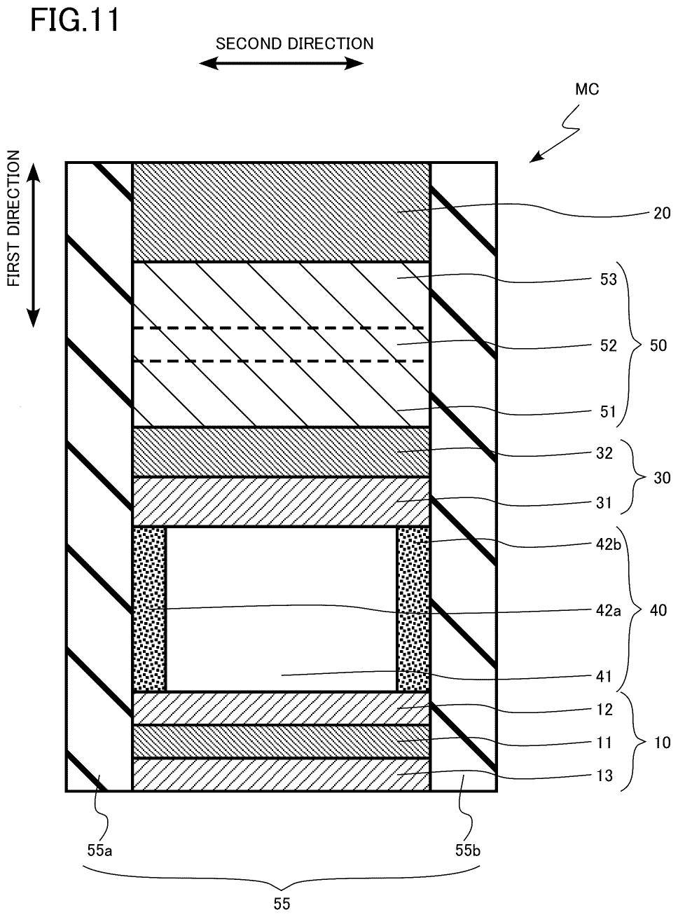

FIG. 11 is a schematic cross-sectional view of a memory cell in the memory device according to the third modification example of the first embodiment. FIG. 11 is a diagram corresponding to FIG. 2 in the first embodiment.

The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the third modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the third modification example of the first embodiment, as in the first embodiment, it is possible to realize a switching element having excellent characteristics such as a low half-select leakage current and high reliability.

According to the first embodiment and its modification examples, it is possible to realize a switching element having excellent characteristics such as a low half-select leakage current and high reliability. Therefore, according to the first embodiment and its modification examples, it is possible to realize a memory device having a switching element with excellent characteristics.

### Second Embodiment

A memory device according to a second embodiment is different from the memory device according to the first embodiment in that the memory device according to the second embodiment is a resistive memory (ReRAM). Hereinafter, the description of a part of the content overlapping the first embodiment will be omitted.

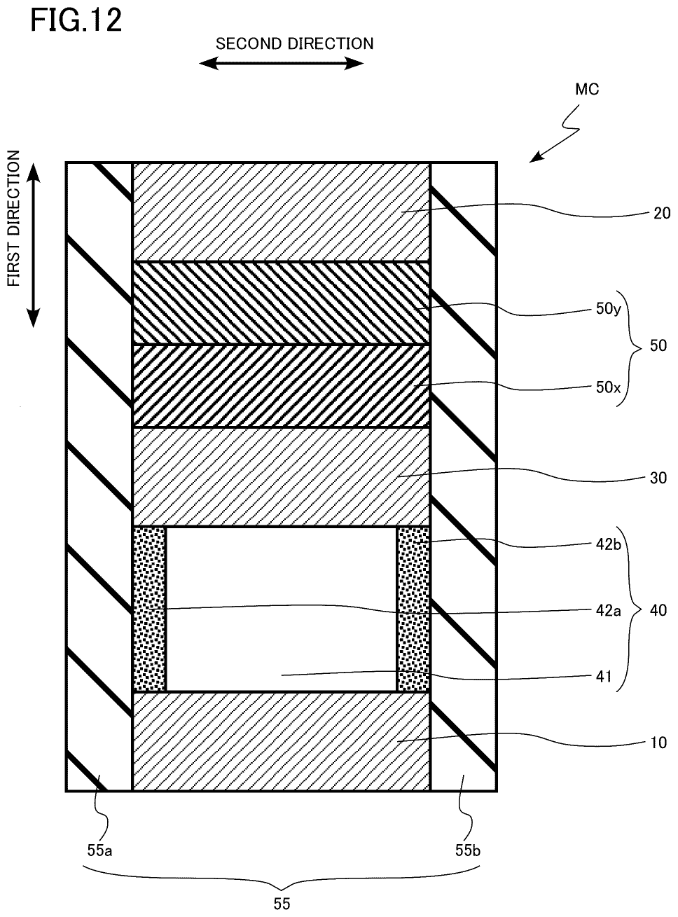

FIG. 12 is a schematic cross-sectional view of a memory cell in the memory device according to the second embodiment. FIG. 12 shows a cross section of one memory cell MC indicated by, for example, a dotted circle in the memory cell array 100 of FIG. 1.

As shown in FIG. 12, the memory cell MC includes a lower electrode 10, an upper electrode 20, an intermediate electrode 30, a switching layer 40, a variable resistance layer 50, and a sidewall insulating layer 55. The switching layer 40 includes an inner region 41, a first sidewall region 42a, and a second sidewall region 42b. The variable resistance layer 50 includes a high resistance layer 50x and a low resistance layer 50y. The sidewall insulating layer 55 includes a first portion 55a and a second portion 55b.

The lower electrode 10 is an example of the first conductive layer. The upper electrode 20 is an example of the second conductive layer. The intermediate electrode 30 is an example of the third conductive layer. The inner region 41 is an example of the first region. The first sidewall region 42a is an example of the second region. The second sidewall region 42b is an example of the third region.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configuration of the switching layer 40 is similar to that in the memory device according to the first embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that its electrical resistance changes with the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

As described above, according to the memory device according to the second embodiment, as in the first embodiment, it is possible to realize a switching element having excellent characteristics such as a low half-select leakage current and high reliability. Therefore, according to the second embodiment, it is possible to realize a memory device having a switching element with excellent characteristics.

### Third Embodiment

A memory device according to a third embodiment includes a memory cell including a first conductive layer, a second conductive layer, and a memory layer provided between the first conductive layer and the second conductive layer. Then, the memory layer contains a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element different from the at least one first element and selected from a group consisting of aluminum (Al), zinc (Zn), tin (Sn), gallium (Ga), indium (In), and bismuth (Bi), and at least one third element selected from a group consisting of tellurium (Te), sulfur (S), selenium (Se), and antimony (Sb). The memory layer includes a first region, a second region, and a third region in a cross section parallel to a first direction connecting the first conductive layer and the second conductive layer. In a second direction perpendicular to the first direction of the cross section, the first region is provided between the second region and the third region. The first region contains a first oxide, and the second region and the third region contains a second oxide of the second element or a third oxide of the third element.

In addition, the memory device according to the third embodiment further includes a plurality of first wirings and a plurality of second wirings crossing the plurality of first wirings. Then, the memory cell is provided in a region where one of the plurality of first wirings crosses one of the plurality of second wirings.

The memory device according to the third embodiment is different from the memory device according to the first and second embodiments in that the memory cell does not include a third conductive layer and a variable resistance layer and includes a configuration similar to the switching layer in the first and second embodiments as a memory layer. Hereinafter, the description of a part of the content overlapping the first and second embodiments will be omitted.

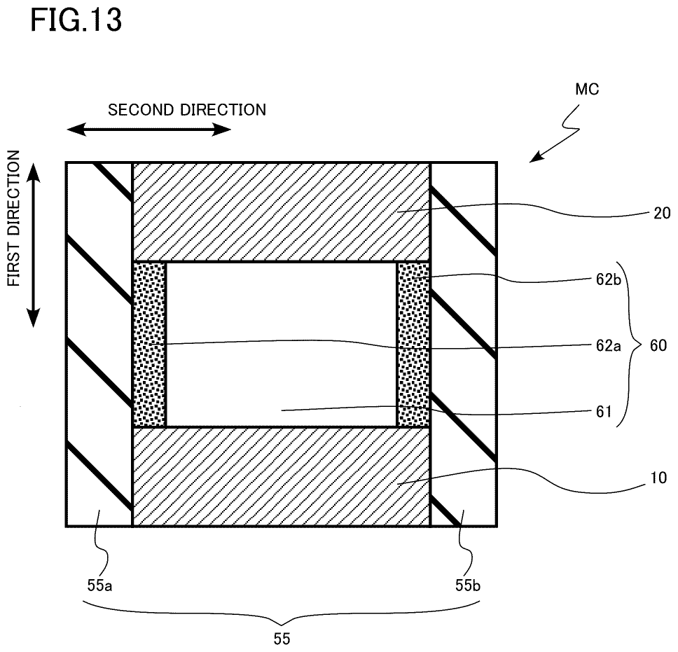

FIG. 13 is a schematic cross-sectional view of a memory cell in the memory device according to the third embodiment. FIG. 13 shows a cross section of one memory cell MC indicated by, for example, a dotted circle in the memory cell array 100 of FIG. 1.

As shown in FIG. 13, the memory cell MC includes a lower electrode 10, an upper electrode 20, a sidewall insulating layer 55, and a memory layer 60. The sidewall insulating layer 55 includes a first portion 55a and a second portion 55b. The memory layer 60 includes an inner region 61, a first sidewall region 62a, and a second sidewall region 62b.

The lower electrode 10 is an example of the first conductive layer. The upper electrode 20 is an example of the second conductive layer.

The lower electrode 10, the memory layer 60, and the upper electrode 20 form a memory element of the memory cell MC. The memory element of the memory cell MC has a switching function and an information storage function.

The memory layer 60 has a configuration similar to that of the switching layer 40 in the first and second embodiments. The inner region 61, the first sidewall region 62a, and the second sidewall region 62b of the memory layer 60 have the same configurations as the inner region 41, the first sidewall region 42a, and the second sidewall region 42b of the switching layer 40 in the first and second embodiments, respectively.

The memory layer 60 has a nonlinear current-voltage characteristic in which a current increases abruptly at a specific threshold voltage. In addition, the memory layer 60 has a characteristic that the threshold voltage changes with the application of a predetermined voltage. The memory layer 60 has a characteristic that its electrical resistance changes with the application of a predetermined voltage. In the third embodiment, the high resistance state is a state in which the resistance of the memory layer 60 is relatively high at the read voltage. In addition, in the third embodiment, the low resistance state is a state in which the resistance of the memory layer 60 is relatively low at the read voltage.

The memory layer 60 has a function of suppressing an increase in half-select leakage current flowing through the half-selected cell. In addition, the memory layer 60 has a function of storing data by resistance change. The memory layer 60 is a single layer and realizes the function of the switching layer 40 and the function of the variable resistance layer 50 in the first and second embodiments.

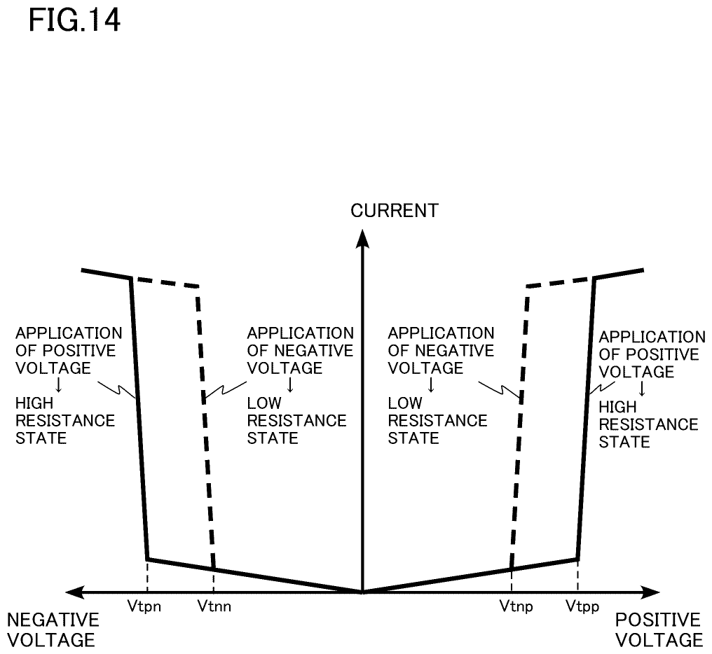

FIG. 14 is an explanatory diagram of the current-voltage characteristic of a memory element according to the third embodiment. The horizontal axis indicates a voltage applied to the memory element, and the vertical axis indicates a current flowing through the memory element. In FIG. 14, the horizontal axis indicates a voltage applied to the upper electrode 20 with the electric potential of the lower electrode 10 as a reference. FIG. 14 shows the current-voltage characteristic of the memory layer 60 in the third embodiment. FIG. 14 shows the current-voltage characteristic of the memory cell MC in the third embodiment.

The memory element according to the third embodiment shows different current-voltage characteristics when a predetermined positive voltage is applied to the upper electrode 20 and when a predetermined negative voltage is applied to the upper electrode 20. In FIG. 14, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is lower than the second negative voltage side threshold voltage Vtnn.

The memory element according to the third embodiment can have a high resistance state and a low resistance state on both the positive voltage side and the negative voltage side. When a predetermined positive voltage is applied to the upper electrode 20, a high resistance state is realized on both the positive voltage side and the negative voltage side. On the other hand, when a predetermined negative voltage is applied to the upper electrode 20, a low resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

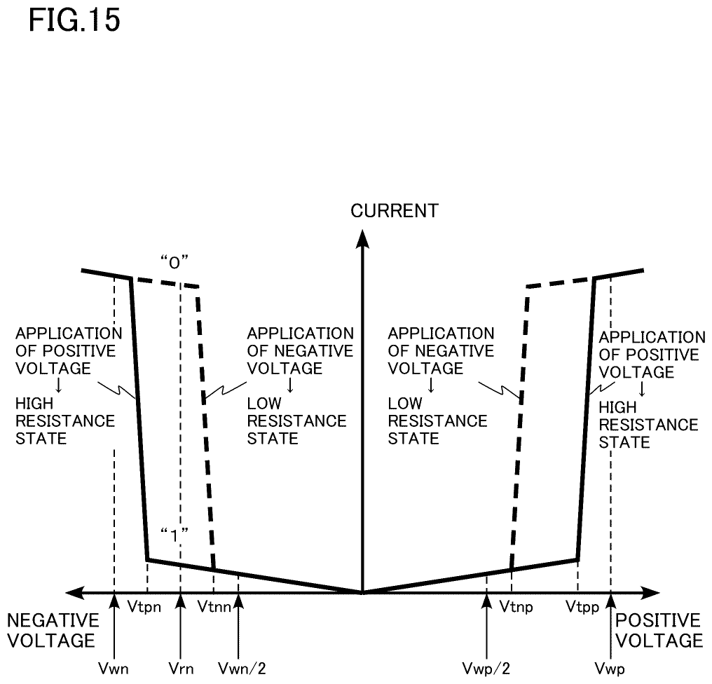

FIG. 15 is an explanatory diagram of a first operation example of the memory operation in the memory device according to the third embodiment. FIG. 15 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the first operation example, the high resistance state and the low resistance state on the negative voltage side are used for the memory operation. In the first operation example, the negative side read voltage Vrn is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In the first operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the first operation example, regardless of whether the data of the selected cell is data “1” or data “0”, the application of the negative side read voltage Vrn does not destroy the data. In other words, in the case of the first operation example, non-destructive reading is possible regardless of whether the data of the selected cell is data “1” or data “0”.

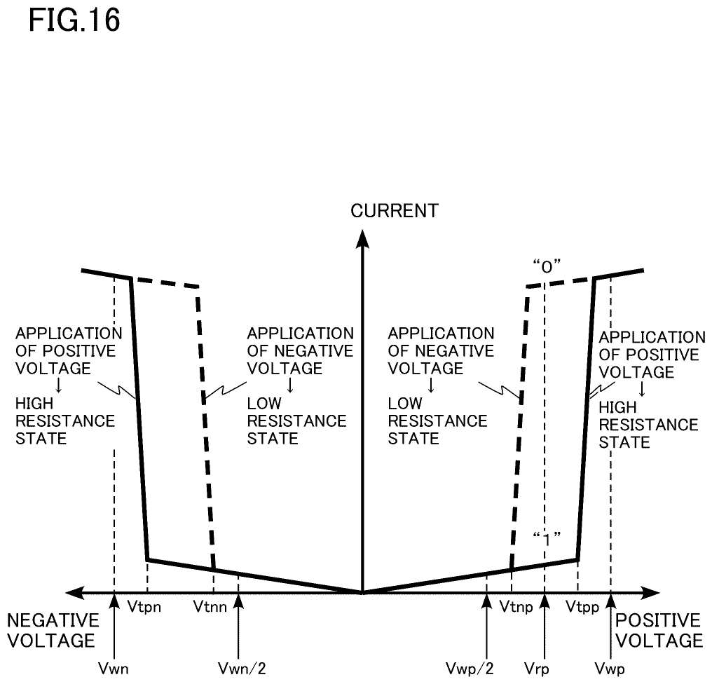

FIG. 16 is an explanatory diagram of a second operation example of the memory operation in the memory device according to the third embodiment. FIG. 16 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the second operation example, the high resistance state and the low resistance state on the positive voltage side are used for the memory operation. In the second operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the positive voltage side, and data “0” is written to the selected cell.

In the second operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the second operation example, when the data of the selected cell is data “1”, the application of the positive side read voltage Vrp does not destroy the data. In other words, in the case of the second operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the second operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

### First Modification Example

A memory device according to a first modification example of the third embodiment is different from the memory device according to the third embodiment in that the current-voltage characteristics of the memory elements are different.

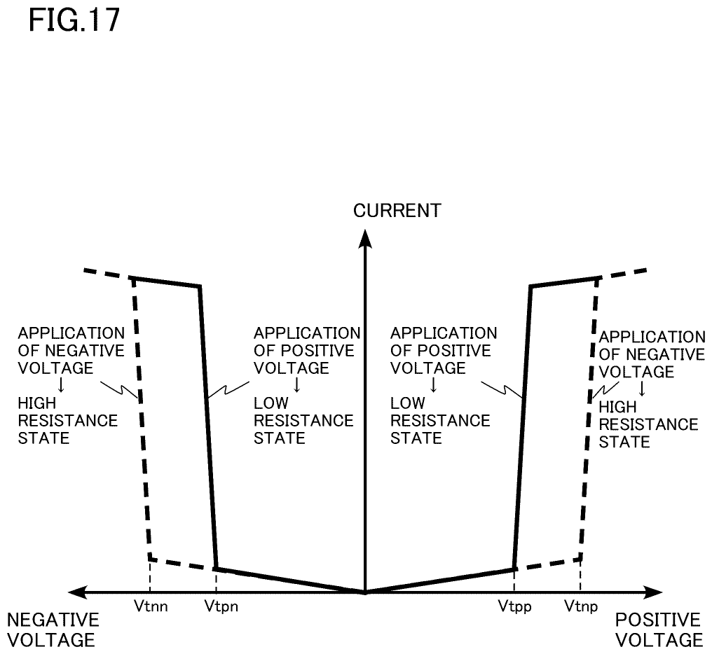

FIG. 17 is an explanatory diagram of the current-voltage characteristic of a memory element according to the first modification example of the third embodiment. The horizontal axis indicates a voltage applied to the memory element, and the vertical axis indicates a current flowing through the memory element. In FIG. 17, the horizontal axis indicates a voltage applied to the upper electrode 20 with the electric potential of the lower electrode 10 as a reference. FIG. 17 shows the current-voltage characteristic of the memory layer 60 in the first modification example of the third embodiment. FIG. 17 shows the current-voltage characteristic of the memory cell MC in the first modification example of the third embodiment.

The memory element according to the first modification example of the third embodiment shows different current-voltage characteristics when a predetermined positive voltage is applied to the upper electrode 20 and when a predetermined negative voltage is applied to the upper electrode 20. In FIG. 17, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at the first positive voltage side threshold voltage Vtpp on the positive voltage side. In addition, when a predetermined positive voltage is applied to the upper electrode 20, the current increases abruptly at the first negative voltage side threshold voltage Vtpn on the negative voltage side.

On the other hand, when a predetermined negative voltage is applied to the upper electrode 20, the current increases abruptly at the second positive voltage side threshold voltage Vtnp on the positive voltage side. In addition, when a predetermined negative voltage is applied to the upper electrode 20, the current increases abruptly at the second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is higher than the second negative voltage side threshold voltage Vtnn.

The memory element according to the first modification example of the third embodiment can have a high resistance state and a low resistance state on both the positive voltage side and the negative voltage side. When a predetermined positive voltage is applied to the upper electrode 20, a low resistance state is realized on both the positive voltage side and the negative voltage side. On the other hand, when a predetermined negative voltage is applied to the upper electrode 20, a high resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

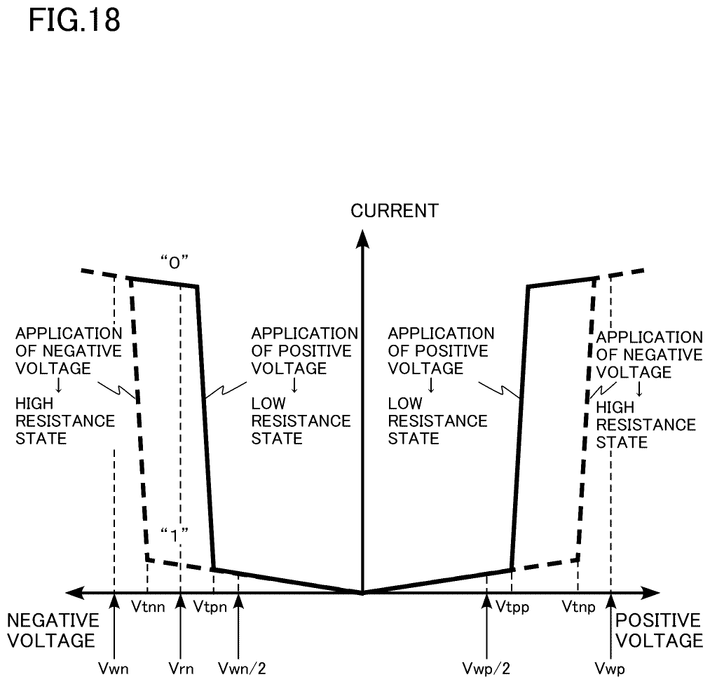

FIG. 18 is an explanatory diagram of a third operation example of the memory operation in the memory device according to the first modification example of the third embodiment. FIG. 18 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the third operation example, the high resistance state and the low resistance state on the negative voltage side are used for the memory operation. In the third operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the negative voltage side, and data “0” is written to the selected cell.

In the third operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the third operation example, when the data of the selected cell is data “1”, the application of the negative side read voltage Vrn does not destroy the data. In other words, in the case of the third operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the third operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

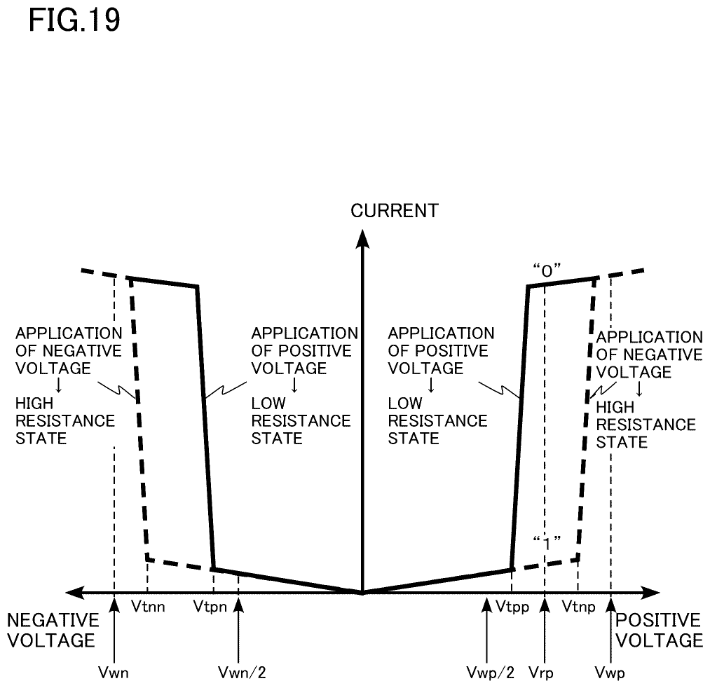

FIG. 19 is an explanatory diagram of a fourth operation example of the memory operation in the memory device according to the first modification example of the third embodiment. FIG. 19 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the fourth operation example, the high resistance state and the low resistance state on the positive voltage side are used for the memory operation. In the fourth operation example, the positive side read voltage Vrp is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In the fourth operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the fourth operation example, regardless of whether the data of the selected cell is data “1” or data “0”, the application of the positive side read voltage Vrp does not destroy the data. In other words, in the case of the fourth operation example, non-destructive reading is possible regardless of whether the data of the selected cell is data “1” or data “0”.

### Second Modification Example

A memory device according to a second modification example of the third embodiment is different from the memory device according to the third embodiment in that the current-voltage characteristics of the memory elements are different.

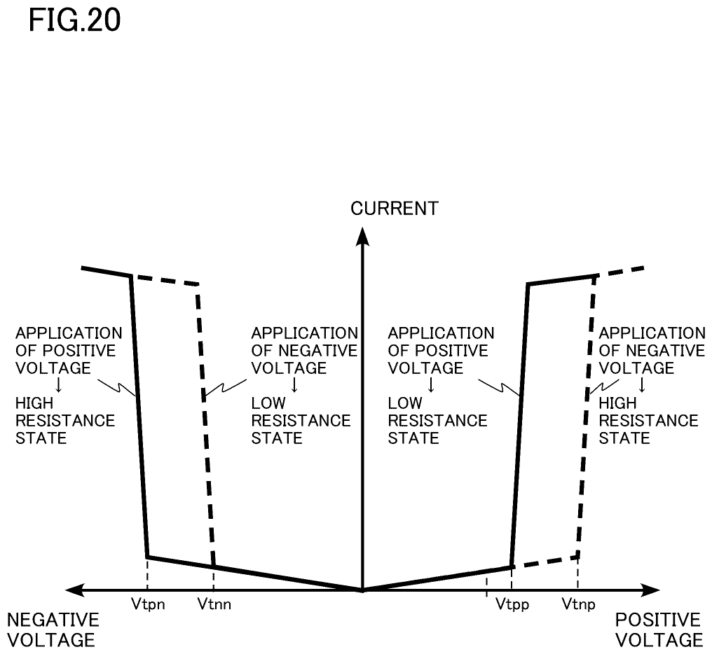

FIG. 20 is an explanatory diagram of the current-voltage characteristic of a memory element according to the second modification example of the third embodiment. The horizontal axis indicates a voltage applied to the memory element, and the vertical axis indicates a current flowing through the memory element. In FIG. 20, the horizontal axis indicates a voltage applied to the upper electrode 20 with the electric potential of the lower electrode 10 as a reference. FIG. 20 shows the current-voltage characteristic of the memory layer 60 in the second modification example of the third embodiment. FIG. 20 shows the current-voltage characteristic of the memory cell MC in the second modification example of the third embodiment.

The memory element according to the second modification example of the third embodiment shows different current-voltage characteristics when a predetermined positive voltage is applied to the upper electrode 20 and when a predetermined negative voltage is applied to the upper electrode 20. In FIG. 20, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at the first positive voltage side threshold voltage Vtpp on the positive voltage side. In addition, when a predetermined positive voltage is applied to the upper electrode 20, the current increases abruptly at the first negative voltage side threshold voltage Vtpn on the negative voltage side.

On the other hand, when a predetermined negative voltage is applied to the upper electrode 20, the current increases abruptly at the second positive voltage side threshold voltage Vtnp on the positive voltage side. In addition, when a predetermined negative voltage is applied to the upper electrode 20, the current increases abruptly at the second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory element according to the second modification example of the third embodiment can have a high resistance state and a low resistance state on both the positive voltage side and the negative voltage side. When a predetermined positive voltage is applied to the upper electrode 20, a low resistance state is realized on the positive voltage side and a high resistance state is realized on the negative voltage side. On the other hand, when a predetermined negative voltage is applied to the upper electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

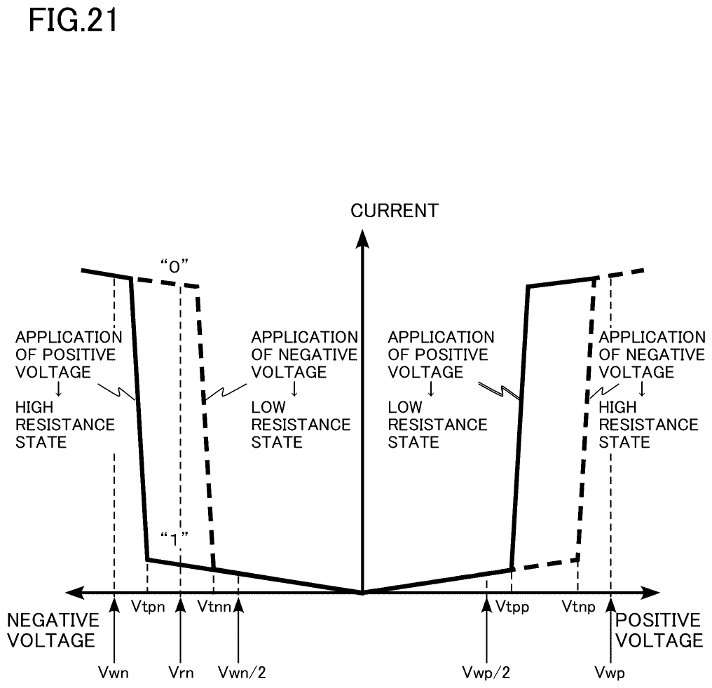

FIG. 21 is an explanatory diagram of a fifth operation example of the memory operation in the memory device according to the second modification example of the third embodiment. FIG. 21 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the fifth operation example, the high resistance state and the low resistance state on the negative voltage side are used for the memory operation. In the fifth operation example, the negative side read voltage Vrn is used as a read voltage.

When writing data “1” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the fifth operation example, regardless of whether the data of the selected cell is data “1” or data “0”, the application of the negative side read voltage Vrn does not destroy the data. In other words, in the case of the fifth operation example, non-destructive reading is possible regardless of whether the data of the selected cell is data “1” or data “0”.

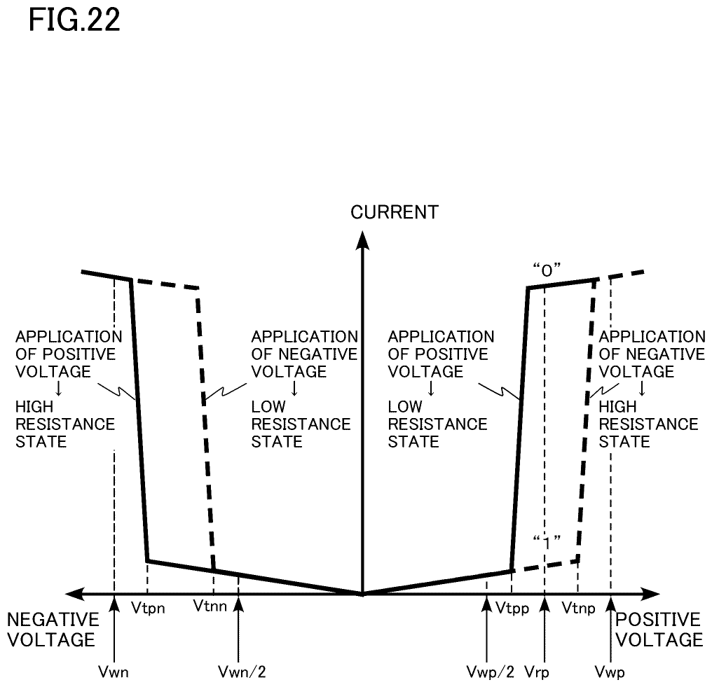

FIG. 22 is an explanatory diagram of a sixth operation example of the memory operation in the memory device according to the second modification example of the third embodiment. FIG. 22 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the sixth operation example, the high resistance state and the low resistance state on the positive voltage side are used for the memory operation. In the sixth operation example, the positive side read voltage Vrp is used as a read voltage.

When writing data “1” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the sixth operation example, regardless of whether the data of the selected cell is data “1” or data “0”, the application of the positive side read voltage Vrp does not destroy the data. In other words, in the case of the sixth operation example, non-destructive reading is possible regardless of whether the data of the selected cell is data “1” or data “0”.

### Third Modification Example

A memory device according to a third modification example of the third embodiment is different from the memory device according to the third embodiment in that the current-voltage characteristics of the memory elements are different.

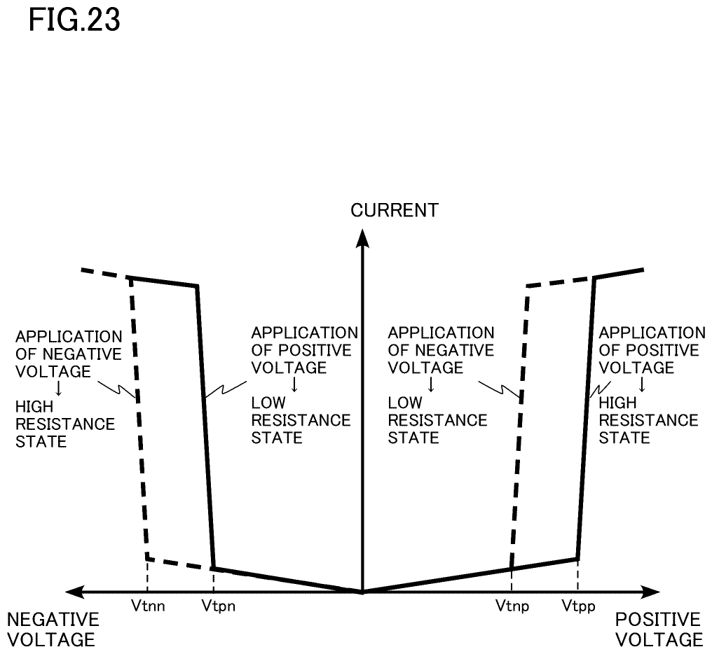

FIG. 23 is an explanatory diagram of the current-voltage characteristic of a memory element according to the third modification example of the third embodiment. The horizontal axis indicates a voltage applied to the memory element, and the vertical axis indicates a current flowing through the memory element. In FIG. 23, the horizontal axis indicates a voltage applied to the upper electrode 20 with the electric potential of the lower electrode 10 as a reference. FIG. 23 shows the current-voltage characteristic of the memory layer 60 in the third modification example of the third embodiment. FIG. 23 shows the current-voltage characteristic of the memory cell MC in the third modification example of the third embodiment.

The memory element according to the third modification example of the third embodiment shows different current-voltage characteristics when a predetermined positive voltage is applied to the upper electrode 20 and when a predetermined negative voltage is applied to the upper electrode 20. In FIG. 23, the solid line indicates a current-voltage characteristic when a predetermined positive voltage is applied to the upper electrode 20, and the dotted line indicates a current-voltage characteristic when a predetermined negative voltage is applied to the upper electrode 20.

When a predetermined positive voltage is applied to the upper electrode 20, the current increases abruptly at the first positive voltage side threshold voltage Vtpp on the positive voltage side. In addition, when a predetermined positive voltage is applied to the upper electrode 20, the current increases abruptly at the first negative voltage side threshold voltage Vtpn on the negative voltage side.

On the other hand, when a predetermined negative voltage is applied to the upper electrode 20, the current increases abruptly at the second positive voltage side threshold voltage Vtnp on the positive voltage side. In addition, when a predetermined negative voltage is applied to the upper electrode 20, the current increases abruptly at the second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is higher than the second negative voltage side threshold voltage Vtnn.

The memory element according to the third modification example of the third embodiment can have a high resistance state and a low resistance state on both the positive voltage side and the negative voltage side. When a predetermined positive voltage is applied to the upper electrode 20, a high resistance state is realized on the positive voltage side and a low resistance state is realized on the negative voltage side. On the other hand, when a predetermined negative voltage is applied to the upper electrode 20, a low resistance state is realized on the positive voltage side and a high resistance state is realized on the negative voltage side. Hereinafter, the high resistance state is defined as data “1”, and the low resistance state is defined as data “0”. The memory cell MC can store 1-bit data of “0” and “1”.

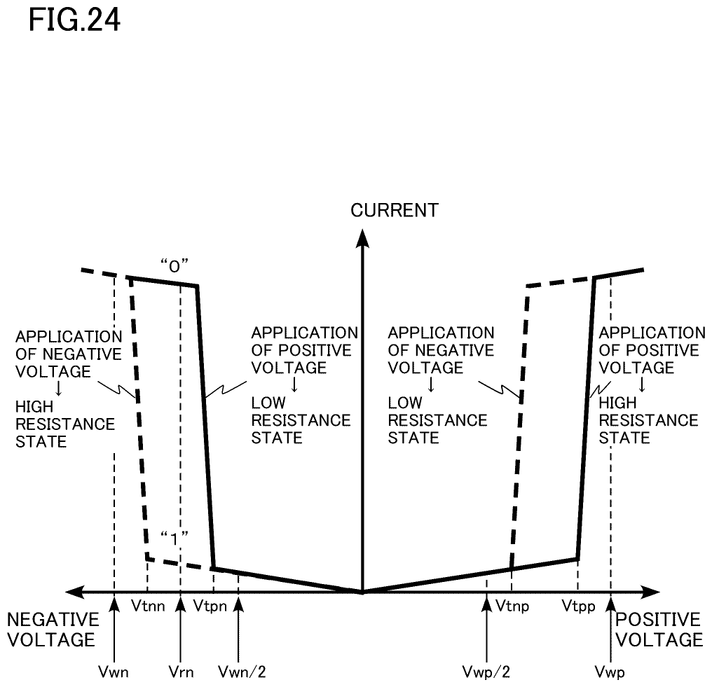

FIG. 24 is an explanatory diagram of a seventh operation example of the memory operation in the memory device according to the third modification example of the third embodiment. FIG. 24 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the seventh operation example, the high resistance state and the low resistance state on the negative voltage side are used for the memory operation. In the seventh operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a low resistance state is realized on the negative voltage side, and data “0” is written to the selected cell.

In the seventh operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, in the seventh operation example, when writing data “0” to the selected cell, assuming that the data stored in the selected cell is data “1”, a current flows if the positive side write voltage Vwp is higher than the second positive voltage side threshold voltage Vtnp even if the positive side write voltage Vwp is lower than the first positive voltage side threshold voltage Vtpp. For this reason, data “0” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the seventh operation example, when the data of the selected cell is data “1”,the application of the negative side read voltage Vrn does not destroy the data. In other words, in the case of the seventh operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the seventh operation example, when the data of the selected cell is data “0”,there is a possibility of destructive reading. Therefore, when the data of the selected cell is data “0”, it may be necessary to rewrite the data “0” in order to maintain the data of the selected cell after reading the data of the selected cell.

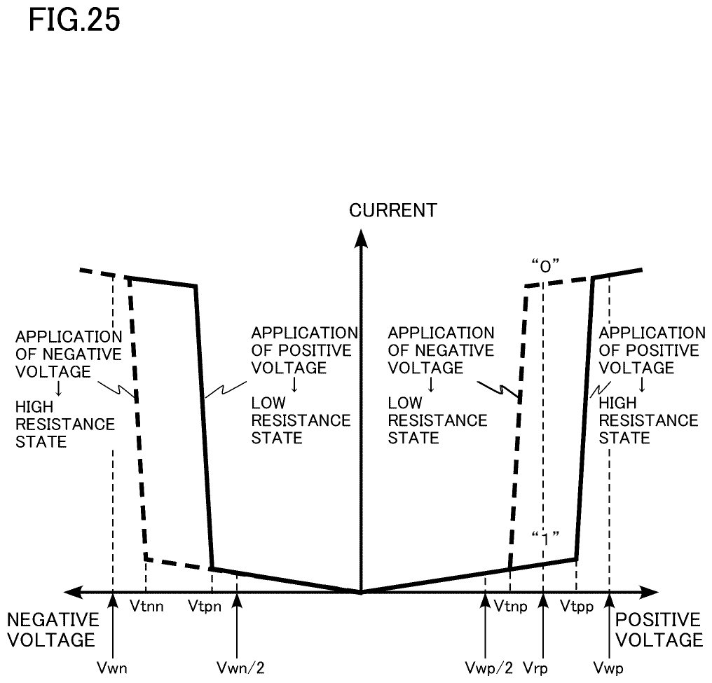

FIG. 25 is an explanatory diagram of an eighth operation example of the memory operation in the memory device according to the third modification example of the third embodiment. FIG. 25 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the eighth operation example, the high resistance state and the low resistance state on the positive voltage side are used for the memory operation. In the eighth operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a low resistance state is realized on the positive voltage side, and data “0” is written to the selected cell.

In the eighth operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, in the eighth operation example, when writing data “0” to the selected cell, assuming that the data stored in the selected cell is data “1”, a current flows if the negative side write voltage Vwn is lower than the first negative voltage side threshold voltage Vtpn even if the negative side write voltage Vwn is higher than the second negative voltage side threshold voltage Vtnn. For this reason, data “0” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the eighth operation example, when the data of the selected cell is data “1”,the application of the positive side read voltage Vrp does not destroy the data. In other words, in the case of the eighth operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the eighth operation example, when the data of the selected cell is data “0”,there is a possibility of destructive reading. Therefore, when the data of the selected cell is data “0”, it may be necessary to rewrite the data “0” in order to maintain the data of the selected cell after reading the data of the selected cell.

In the memory devices according to the third embodiment and its modification examples, the memory element of the memory cell MC has a switching function and an information storage function. The memory layer 60 is a single layer and realizes the function of the switching layer 40 and the function of the variable resistance layer 50 in the first and second embodiments. Since the memory layer 60 in the third embodiment is a single layer and has a switching function and a memory function, the structure of the memory cell MC can be made very simple.

In addition, the memory layer 60 of each memory device according to the third embodiment and its modification examples has the same configuration as the switching layer 40 in the first and second embodiments. Therefore, according to the third embodiment and its modification examples, as in the first and second embodiments, it is possible to realize a memory device having excellent switching characteristics such as a low half-select leakage current and high reliability.

In addition, the plurality of current-voltage characteristics of the memory elements shown in the third embodiment and its modification examples can be realized, for example, by adopting the memory layer 60 having an appropriate chemical composition.

Although the magnetoresistive memory has been described as an example of the two-terminal memory device in the first embodiment and the resistive memory has been described as an example of the memory device in the second embodiment, embodiments can be applied to other two-terminal memory devices. For example, embodiments can be applied to a phase change memory (PCM) or a ferroelectric random access memory (FeRAM).

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer,
wherein the switching layer contains a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element different from the at least one first element and selected from a group consisting of aluminum (Al), zinc (Zn), tin (Sn), gallium (Ga), indium (In), and bismuth (Bi), and at least one third element selected from a group consisting of tellurium (Te), sulfur (S), selenium (Se), and antimony (Sb),
the switching layer includes a first region, a second region, and a third region in a cross section parallel to a first direction connecting the first conductive layer and the second conductive layer, and the first region is provided between the second region and the third region in a second direction perpendicular to the first direction of the cross section, and
the first region contains the first oxide, and the second region and the third region contain a second oxide of the second element or a third oxide of the third element.

2. The memory device according to claim 1,
wherein the second region and the third region contain the second oxide and the third oxide.

3. The memory device according to claim 1,
wherein the first region contains or does not contain the second oxide, and a concentration of the second oxide in the second region and a concentration of the second oxide in the third region are higher than a concentration of the second oxide in the first region, or
the first region contains or does not contain the third oxide, and a concentration of the third oxide in the second region and a concentration of the third oxide in the third region are higher than a concentration of the third oxide in the first region.

4. The memory device according to claim 1,
wherein the switching layer contains a compound of the second element and the third element.

5. The memory device according to claim 4,
wherein the first region contains the compound,
the second region and the third region contain or do not contain the compound, and
a concentration of the compound in the second region and a concentration of the compound in the third region are lower than a concentration of the compound in the first region.

6. The memory device according to claim 1,
wherein a ratio of a sum of atomic concentrations of the first element, the second element, and the third element to a sum of atomic concentrations of the first element, the second element, the third element, and oxygen in the second region and the third region is lower than a ratio of a sum of atomic concentrations of the first element, the second element, and the third element to a sum of atomic concentrations of the first element, the second element, the third element, and oxygen in the first region.

7. The memory device according to claim 1,
wherein an atomic concentration of the second element in the second region and an atomic concentration of the second element in the third region are higher than an atomic concentration of the second element in the first region, or
an atomic concentration of the third element in the second region and an atomic concentration of the third element in the third region are higher than an atomic concentration of the third element in the first region.

8. The memory device according to claim 1,
wherein the second region and the third region are provided between the first conductive layer and the third conductive layer in the first direction.

9. The memory device according to claim 1,
wherein the switching layer further contains at least one fourth element selected from a group consisting of carbon (C), boron (B), and nitrogen (N).

10. The memory device according to claim 1,
wherein a ratio of a sum of atomic concentrations of the first element and oxygen (O) to a sum of atomic concentrations of the first element, the second element, the third element, and oxygen (O) in the switching layer is equal to or more than 5% and equal to or less than 90%.

11. The memory device according to claim 1, further comprising:
an insulating layer including a first portion and a second portion, the first conductive layer, the third conductive layer, and the switching layer being provided between the first portion and the second portion in the second direction of the cross section, and
the second region is in contact with the first portion, and the third region is in contact with the second portion.

12. The memory device according to claim 1,
wherein the first conductive layer, the second conductive layer, or the third conductive layer contains at least one material selected from a group consisting of carbon, carbon nitride, tungsten, tungsten carbide, tungsten nitride, titanium, titanium nitride, tantalum, tantalum carbide, and tantalum nitride.

13. The memory device according to claim 1,
wherein the first conductive layer, the second conductive layer, or the third conductive layer contains at least one material selected from a group consisting of hafnium, hafnium boride, aluminum magnesium boride, zirconium, zirconium boride, and titanium boride.

14. The memory device according to claim 1,
wherein the variable resistance layer includes a magnetic tunnel junction.

15. The memory device according to claim 1,
wherein the variable resistance layer has an electrical resistance changing with application of a predetermined voltage, and
the switching layer has a nonlinear current-voltage characteristic that a current increases at a specific threshold voltage.

16. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.

17. A memory device, comprising:
a memory cell including a first conductive layer, a second conductive layer, and a memory layer provided between the first conductive layer and the second conductive layer,
wherein the memory layer contains a first oxide of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element different from the at least one first element and selected from a group consisting of aluminum (Al), zinc (Zn), tin (Sn), gallium (Ga), indium (In), and bismuth (Bi), and at least one third element selected from a group consisting of tellurium (Te), sulfur (S), selenium (Se), and antimony (Sb),
the memory layer includes a first region, a second region, and a third region in a cross section parallel to a first direction connecting the first conductive layer and the second conductive layer, and the first region is provided between the second region and the third region in a second direction perpendicular to the first direction of the cross section, and
the first region contains the first oxide, and the second region and the third region contain a second oxide of the second element or a third oxide of the third element.

18. The memory device according to claim 17,
wherein the second region and the third region contain the second oxide and the third oxide.

19. The memory device according to claim 17,
wherein the memory layer contains a compound of the second element and the third element.

20. The memory device according to claim 17,
wherein the memory layer has a nonlinear current-voltage characteristic that a current increases at a specific threshold voltage, and the threshold voltage changes with application of a predetermined voltage.

21. The memory device according to claim 17, further comprising:
a plurality of first wirings; and
a plurality of second wirings crossing the plurality of first wirings,
wherein the memory cell is provided in a region where one of the plurality of first wirings and one of the plurality of second wirings cross each other.
